(19) United States
(12) Patent Application Publication
(10) Pub. No.: US 2024/0199433 A1
(43) Pub. Date: Jun. 20, 2024

(54) NON-METALLIC HIGH-ENTROPY COMPOUND, AND PREPARATION METHOD AND USE THEREOF

(71) Applicant: GUANGZHOU UNIVERSITY, Guangzhou (CN)

(72) Inventors: Zhaoqing LIU, Guangzhou (CN); Jingwei LI, Guangzhou (CN); Kang XIAO, Guangzhou (CN)

(73) Assignee: GUANGZHOU UNIVERSITY, Guangzhou (CN)

(21) Appl. No.: 18/387,919

(22) Filed: Nov. 8, 2023

(30) Foreign Application Priority Data
Dec. 15, 2022 (CN) 202211620104.3

(51) Int. Cl. C01B 35/00; B01J 27/20; B01J 27/24; B01J 35/00; C01B 3/32; C01B 33/10; C01B 35/14; C23C 16/30; C23C 16/40; C23C 16/448; C25B 1/04; C25B 11/075; C25B 11/077; C25D 9/04; H01M 4/485; H01M 4/58; H01M 10/054

(52) U.S. Cl. CPC C01B 35/00; B01J 27/20; B01J 27/24; B01J 35/004; C01B 3/326; C01B 33/10; C01B 35/14; C23C 16/305; C23C 16/40; C23C 16/4482; C25B 1/04; C25B 11/075; C25B 11/077; C25D 9/04; H01M 4/485; H01M 4/5815; H01M 4/582; H01M 10/054; C01B 2203/0238; C01B 2203/1041

(57) ABSTRACT

The present disclosure relates to the technical field of photocatalysis/electrocatalysis, and in particular to a non-metallic high-entropy compound, and a preparation method and use thereof. In the present disclosure, the non-metallic high-entropy compound includes at least five non-metallic elements, where each of the at least five non-metallic elements has a molar proportion of 0.1% to 99.0%, and a total atomic proportion of the at least five non-metallic elements are 100%. The non-metallic high-entropy compound has a controllable band gap, an adjustable conductivity, and a desirable surface activity, and shows a catalytic reaction activity for hydrogen production by high-efficiency photocatalytic/electrocatalytic water splitting, carbon dioxide reduction, or organic pollutant degradation. Moreover, synthetic raw materials are all non-metals, which are cheap and easily available, while a synthesis process is simple and easy to implement.

### CROSS REFERENCE TO RELATED APPLICATION

This patent application claims the benefit and priority of Chinese Patent Application No. 202211620104.3, filed with the China National Intellectual Property Administration on Dec. 15, 2022, the disclosure of which is incorporated by reference herein in its entirety as part of the present application.

### TECHNICAL FIELD

The present disclosure relates to the technical field of photocatalysis/electrocatalysis, and in particular to a non-metallic high-entropy compound, and a preparation method and use thereof.

### BACKGROUND

Photoelectrocatalysis is a technology that couples light energy and electrical energy to drive catalysis, and can be simply described as a coupled synergistic catalysis technology of photocatalysis and electrocatalysis. Photocatalysis is a technology that uses light energy (such as sunlight) to complete the catalytic process; compared with the photocatalysis, electrocatalysis is driven by electrical energy, and is widely used due to high efficiency and convenient conversion. A combination of the photocatalysis and the electrocatalysis can not only reduce energy consumption by utilizing an activity of the photocatalysis, but also improve a catalytic efficiency by utilizing the electrocatalysis.

Photocatalysis/electrocatalysis technology has mild reaction conditions and environmental friendliness, and is one of the most promising technologies for hydrogen production by catalytic water splitting, carbon dioxide reduction, and organic pollutant degradation. In order to further improve a photocatalytic/electrocatalytic efficiency, it is an urgent technical problem that those skilled in the art need to solve for preparing photocatalytic/electrocatalytic materials with an excellent performance.

Currently, a variety of catalytic materials have been disclosed in the prior art, such as noble metal-based materials, transition metal-based materials, and non-metallic carbon-based materials. Catalytic materials based on noble metals and transition metals, such as high-entropy alloys and high-entropy oxides, have demonstrated a certain catalytic activity and have been widely studied. However, these materials show relatively high-cost synthetic raw materials, and exhibit catalytic activity and stability that are difficult to meet the needs of commercial applications. As a result, carbon materials composed of non-metallic elements have a wide range of raw material sources and are considered to be one of the material systems with the greatest application potential.

However, existing non-metallic carbon materials have a poor catalytic activity due to limited catalytic active sites. Therefore, there is an urgent need to develop novel non-metallic catalytic materials with a wide range of active sites and a high catalytic activity. In view of this, the present disclosure is specifically proposed.

### SUMMARY

An objective of the present disclosure is to provide a non-metallic high-entropy compound, and a preparation method and use thereof. In the present disclosure, the non-metallic high-entropy compound has a controllable band gap, an adjustable conductivity, and a desirable surface activity.

The present disclosure provides a non-metallic high-entropy compound, including at least five non-metallic elements, where each of the at least five non-metallic elements has a molar proportion of 0.1% to 99.0%, and a total atomic proportion of the at least five non-metallic elements are 100%.

In the present disclosure, the non-metallic high-entropy compound includes at least five non-metallic elements. This compound is different from a traditional carbon-based material system that is doped with heterogeneous elements (such as N and S) to improve a coordination environment of the material and to introduce limited active sites. The five or more non-metallic elements of the non-metallic high-entropy compound are evenly distributed in an entire material system, and these elements coordinate with each other to form bonds. Due to a difference in electronegativity of these atoms, the non-metallic high-entropy compound has a controllable surface atomic coordination environment and widely distributed active sites, thereby achieving a high catalytic activity.

Specifically, the at least five non-metallic elements are selected from the group consisting of hydrogen, boron, carbon, nitrogen, oxygen, fluorine, phosphorus, sulfur, selenium, chlorine, bromine, iodine, and silicon.

The present disclosure further provides a preparation method of the non-metallic high-entropy compound, including the following steps:
S1, mixing at least five non-metallic element sources evenly to obtain a precursor solution; and
S2, converting the precursor solution into the non-metallic high-entropy compound through solvothermal polymerization, vapor deposition, or electrochemical deposition.

Preferably, the non-metallic element source is one or a combination of two or more selected from the group consisting of an inorganic non-metallic acid, an inorganic non-metallic oxide, and a non-metallic organic substance.

The inorganic non-metallic acid includes but is not limited to boric acid (H₃BO₃), carbonic acid (HCO₃), nitric acid (HNO₃), hydrofluoric acid (HF), phosphoric acid (H₃PO₄), sulfuric acid (H₂SO₄), selenic acid (H₂SeO₄), hydrochloric acid (HCl), hypochlorous acid (HClO), perchloric acid (HClO₄), hydrobromic acid (HBr), bromic acid (HBrO₃), hydriodic acid (HI), iodic acid (HIO₃), and silicic acid (H₂SiO₃).

The inorganic non-metallic oxide includes but is not limited to diboron trioxide (B₂O₃), carbon dioxide (CO₂), nitric oxide (NO), nitrogen dioxide (NO₂), phosphorus pentoxide (P₂O₅), sulfur dioxide (SO₂), sulfur trioxide (SO₃), selenium oxide (SeO), selenium dioxide (SeO₂), selenium trioxide (SeO₃), chlorine monoxide (ClO), chlorine dioxide (ClO₂), chlorine trioxide (ClO₃), dichlorine oxide (Cl₂O), dichlorine dioxide (Cl₂O₂), dichlorine trioxide (Cl₂O₃), dibromine monoxide (Br₂O), bromine dioxide (BrO₂), bromine trioxide (BrO₃), iodine pentoxide (I₂O₅), iodine heptaoxide (I₂O₇), and silicon dioxide (SiO₂).

The non-metallic organic substance includes but is not limited to thiourea, thiol, N,N-dimethylformamide, dimethylpyrrolidone, cyanuric chloride, ethoxy(pentafluoro)cyclotriphosphazene, thioacetamide, methyl-hydroselenide, trimethylsilyl acetate, tri-tert-butyl borate, and carbamide.

Considering the stability and availability of raw materials, the non-metallic element source is preferably boric acid, hydrogen iodide, diboron trioxide, cyanuric chloride, ethoxy(pentafluoro)cyclotriphosphazene, thioacetamide, methyl-hydroselenide, trimethylsilyl acetate, tri-tert-butyl borate, and carbamide.

In the present disclosure, there is preferably no strict limitation on a method for uniformly mixing the non-metallic element sources, and the method includes but is not limited to mixing by dissolving, mixing by stirring, and mixing by grinding; during the mixing by dissolving, the at least five non-metallic elements are uniformly dispersed under stirring in a mixed solvent of ethanol and water at a volume ratio of 1:(0.5-1.5). An aqueous solution of the organic solvent can effectively ensure that the inorganic non-metallic element sources and the organic non-metallic element sources are fully dissolved, thereby ensuring the adequacy and efficiency of the reaction. Therefore, the mixed solvent of the present disclosure can also be obtained by mixing water with other organic solvents, such as acetone, methanol, diethyl ether, ethyl acetate, and carbon tetrachloride; where the ethanol has the lowest toxicity and is the most widely used.

In the present disclosure, the precursor solution can be converted into the non-metallic high-entropy compound through solvothermal polymerization, vapor deposition, or electrochemical deposition. The solvothermal polymerization includes one of a hydrothermal reaction and a calcination polymerization reaction; the hydrothermal reaction is conducted at 80° C. to 200° C. for 6 h to 36 h; and the calcination polymerization reaction is conducted at 500° ° C. to 700° C. for 1 h to 4 h.

Preferably, the vapor deposition specifically includes: introducing an inert gas such as nitrogen into the precursor solution, and introducing the precursor solution into a tubular furnace in a bubbling manner to allow a reaction at a bubbling gas flow rate of 40 mL/min to 60 mL/min and a roasting temperature of 500° C. to 700° C. for 8 h to 12 h.

Preferably, the electrochemical deposition specifically includes: connecting an electrochemical workstation to the precursor solution to construct a three-electrode system, and conducting a reaction at a constant voltage of −20 V for 8 h to 12 h, where the three-electrode system includes a reference electrode made of an Ag/AgCl electrode, and a working electrode and a counter electrode made of conductive glass.

Finally, a substance obtained by the solvothermal polymerization, vapor deposition, or electrochemical deposition is subjected to centrifugation and vacuum drying to obtain non-metallic high-entropy compounds of different compositions. In the present disclosure, there is no strict limitation on conditions for the centrifugation and vacuum drying.

The present disclosure further provides use of the non-metallic high-entropy compound in hydrogen production by photocatalytic/electrocatalytic decomposition, carbon dioxide reduction, organic pollutant degradation, or an energy-storage electrode material such as a sodium-ion battery, which should also belong to the protection scope of the present disclosure.

In the present disclosure, the non-metallic high-entropy compound has at least the following technical effects:
1. In the present disclosure, the non-metallic high-entropy compound has a controllable band gap, an adjustable conductivity, and a desirable surface activity.
2. In the present disclosure, the non-metallic high-entropy compound shows a catalytic reaction activity for hydrogen production by high-efficiency photocatalytic/electrocatalytic water splitting, carbon dioxide reduction, or organic pollutant degradation.
3. In the preparation method of the non-metallic high-entropy compound provided by the present disclosure, synthetic raw materials are all non-metals, which are cheap and easily available, while a synthesis process is simple and easy to implement.

### DETAILED DESCRIPTION OF THE EMBODIMENTS

It should be noted that the following detailed descriptions are exemplary and are intended to provide further descriptions of the present disclosure. Unless otherwise specified, all technical and scientific terms used herein have the same meaning as commonly understood by one of ordinary skill in the art to which this application belongs.

It should be noted that the terminology used herein is for the purpose of describing particular embodiments only and is not intended to limit exemplary embodiments according to the present disclosure. As used herein, unless otherwise specified herein, the singular forms are also intended to include the plural forms. In addition, it should also be understood that when the terms “comprise” and/or “include” are used in this specification, they specify the presence of features, steps, operations, devices, components, and/or combinations thereof.

The technical solution in the present disclosure will be clearly and completely described below in conjunction with the examples of the present disclosure. Apparently, the described examples are a part of, but not all of, the examples of the present disclosure. All other embodiments obtained by those skilled in the art based on the embodiments of the present disclosure without creative efforts shall fall within the protection scope of the present disclosure.

EXAMPLE 1

### Non-Metallic High-Entropy Compound B_{0.15}C_{0.20}N_{0.30}P_{0.20}S_{0.15}

S1, 2 mmol of boric acid (H₃BO₃), 0.5 mmol of cyanuric chloride (C₃Cl₃N₃), 0.5 mmol of ethoxy(pentafluoro)cyclotriphosphazene (C₂H₅F₅N₃OP₃), and 2 mmol of thioacetamide (CH₃CSNH₂) were evenly dispersed in 80 mL of a mixed solvent of ethanol and water (volume ratio of 1:1) under stirring to obtain a precursor solution; and
S2, the precursor solution was transferred into a 100 mL stainless steel reactor lined with polytetrafluoroethylene, and then reacted in an oven at 100° C. for 36 h; a resulting product was subjected to centrifugation and vacuum drying to obtain the B_{0.15}C_{0.20}N_{0.30}P_{0.20}S_{0.15}, with molar proportions of component elements approximately as follows: B (15%), C (20%), N (30%), P (20%), and S (15%).

### EXAMPLE 2

### Non-Metallic High-Entropy Compound B_{0.01}C_{0.08}N_{0.70}P_{0.20}S_{0.01}

S1, 2 mmol of boric acid (H₃BO₃), 1 mmol of cyanuric chloride (C3Cl₃N₃), 1 mmol of ethoxy(pentafluoro)cyclotriphosphazene (C₂H₅F₅N₃OP₃), and 2 mmol of thioacetamide (CH₃CSNH₂) were evenly dispersed in 80 mL of a mixed solvent of ethanol and water (volume ratio of 1:0.5) under stirring to obtain a precursor solution; and
S2, the precursor solution was transferred into a 100 mL stainless steel reactor lined with polytetrafluoroethylene, and then reacted in an oven at 120° C. for 24 h; a resulting product was subjected to centrifugation and vacuum drying to obtain the B0.01C_{0.08}N_{0.70}P_{0.20}S_{0.01}, with molar proportions of component elements approximately as follows: B (1%), C (8%), N (70%), P (20%), and S (1%).

### EXAMPLE 3

### Non-Metallic High-Entropy Compound B_{0.005}C_{0.08}N_{0.90}P_{0.04}S_{0.005}

S1, 0.5 mmol of boric acid (H₃BO₃), 2 mmol of cyanuric chloride (C3Cl₃N₃), 2 mmol of ethoxy(pentafluoro)cyclotriphosphazene (C₂H₅F₅N₃OP₃), and 0.5 mmol of thioacetamide (CH₃CSNH₂) were evenly dispersed in 80 mL of a mixed solvent of ethanol and water volume ratio of (1:1.5) under stirring to obtain a precursor solution; and
S2, the precursor solution was transferred into a 100 mL stainless steel reactor lined with polytetrafluoroethylene, and then reacted in an oven at 160° C. for 12 h; a resulting product was subjected to centrifugation and vacuum drying to obtain the B_{0.005}C_{0.05}N_{0.90}P_{0.04}S_{0.005}, with molar proportions of component elements approximately as follows: B (0.5%), C (5%), N (90%), P (4%), and S (0.5%).

### EXAMPLE 4

### Non-Metallic High-Entropy Compound B_{0.05}C_{0.12}N_{0.20}P_{0.15}S_{0.12}Se_{0.12}Si_{0.12}O_{0.12}

S1, 1 mmol of boric acid (H₃BO₃), 0.5 mmol of cyanuric chloride (C₃Cl₃N₃), 0.5 mmol of ethoxy(pentafluoro)cyclotriphosphazene (C₂H₅F₅N₃OP₃), 1 mmol of thioacetamide (CH₃CSNH₂), 1 mmol of methyl-hydroselenide (CH₄Se), and 1 mmol of trimethylsilyl acetate (C₅H₁₂OSi) were evenly dispersed in 80 mL of a mixed solvent of ethanol and water (volume ratio of 1:1) under stirring to obtain a precursor solution; and
S2, the precursor solution was transferred into a 100 mL stainless steel reactor lined with polytetrafluoroethylene, and then reacted in an oven at 180° C. for 10 h; a resulting product was subjected to centrifugation and vacuum drying to obtain the B0.05C_{0.12}N_{0.20}P_{0.15}S_{0.12}Se_{0.12}Si_{0.12}O_{0.12}, with molar proportions of component elements approximately as follows: B (5%), C (12%), N (20%), P (15%), S (12%), Se (12%), Si (12%), and O (12%).

### EXAMPLE 5

### Non-Metallic High-Entropy Compound B_{0.13}C_{0.20}N_{0.30}P_{0.20}S_{0.12}I_{0.05}

S1, 2 mmol of boric acid (H₃BO₃), 0.5 mmol of cyanuric chloride (C3Cl₃N₃), 0.5 mmol of ethoxy(pentafluoro)cyclotriphosphazene (C₂H₅F₅N₃OP₃), 2 mmol of thioacetamide (CH₃CSNH₂), and 2 mmol of hydrogen iodide (HI) were evenly dispersed in 80 mL of a mixed solvent of ethanol and water (volume ratio of 1:1) under stirring to obtain a precursor solution; and
S2, the precursor solution was transferred into a 100 mL stainless steel reactor lined with polytetrafluoroethylene, and then reacted in an oven at 200° C. for 6 h; a resulting product was subjected to centrifugation and vacuum drying to obtain the B_{0.13}C_{0.20}N_{0.30}P_{0.20}S_{0.12}I_{0.05}, with molar proportions of component elements approximately as follows: B (13%), C (20%), N (30%), P (20%), S (12%), and I (5%).

### EXAMPLE 6

### Non-Metallic High-Entropy Compound B_{0.10}C_{0.22}N_{0.33}P_{0.23}S_{0.12}

S1, 1 mmol of boric acid (H₃BO₃), 0.5 mmol of carbamide (CH₄N₂O), 0.5 mmol of ethoxy(pentafluoro)cyclotriphosphazene (C₂H₅F₅N₃OP₃), and 1 mmol of thioacetamide (CH₃CSNH₂) were ground and mixed uniformly to obtain a precursor solution; and
S2, the precursor solution was calcined in a tubular furnace at 550° C. for 2 h under a nitrogen atmosphere to obtain the B_{0.15}C_{0.20}N_{0.30}P_{0.20}S_{0.15}, with molar proportions of component elements approximately as follows: B (10%), C (22%), N (33%), P (23%), and S (12%).

### EXAMPLE 7

### Non-Metallic High-Entropy Compound B_{0.07}C_{0.12}N_{0.70}P_{0.08}S_{0.03}

S1, 1.2 mmol of boric acid (H₃BO₃), 1.0 mmol of cyanuric chloride (C₃Cl₃N₃), 1.0 mmol of ethoxy(pentafluoro)cyclotriphosphazene (C₂H₅F₅N₃OP₃), and 1.2 mmol of thioacetamide (CH₃CSNH₂) were evenly dispersed in 80 mL of a mixed solvent of ethanol and water (volume ratio of 1:1) under stirring to obtain a precursor solution; and
S2, nitrogen with a flow rate of 50 mL/min was introduced into the precursor solution, and then introduced in the form of bubbling into a 550° C. tubular furnace to allow a reaction for 10 h to obtain the B_{0.07}C_{0.12}N_{0.7}P_{0.08}S_{0.03}, with molar proportions of component elements approximately as follows: B (7%), C (12%), N (70%), P (8%), and S (3%).

### EXAMPLE 8

### Non-Metallic High-Entropy Compound B_{0.10}C_{0.05}N_{0.8}P_{0.04}S_{0.01}

S1, 1.5 mmol of boric acid (H₃BO₃), 0.5 mmol of cyanuric chloride (C₃Cl₃N₃), 1.5 mmol of ethoxy(pentafluoro)cyclotriphosphazene (C₂H₅F₅N₃OP₃), and 0.5 mmol of thioacetamide (CH₃CSNH₂) were evenly dispersed in 80 mL of a mixed solvent of ethanol and water (volume ratio of 1:1) under stirring to obtain a precursor solution; and
S2, an electrochemical workstation was connected to the precursor solution to build a three-electrode system, where a reference electrode was an Ag/AgCl electrode, and a working electrode and a counter electrode were conductive glass; after 10 h of continuous reaction at a constant voltage of −20 V, a product was obtained as the B_{0.10}C_{0.05}N_{0.8}P_{0.04}S_{0.01}, with molar proportions of component elements approximately as follows: B (10%), C (5%), N (80%), P (4%), and S (1%).

### EXAMPLE 9

### Non-Metallic High-Entropy Compound C_{0.09}Si_{0.09}Se_{0.04}F_{0.26}Cl_{0.26}Br_{0.26}

S1, 2 mmol of chlorine dioxide (ClO₂), 2 mmol of hydrobromic acid (HBr), 2 mmol of hydrofluoric acid (HF), 2 mmol of methyl-hydroselenide (CH₄Se), and 2 mmol of trimethylsilyl acetate (C₅H₁₂OSi) were evenly dispersed in 80 mL of a mixed solvent of ethanol and water (volume ratio of 1:1) under stirring to obtain a precursor solution; and
S2, nitrogen with a flow rate of 50 mL/min was introduced into the precursor solution, and then introduced in the form of bubbling into a 700° C. tubular furnace to allow a reaction for 8 h to obtain the C_{0.09}Si_{0.09}Se_{0.04}F_{0.26}Cl_{0.26}Br_{0.26}, with molar proportions of component elements approximately as follows: C (9%), Si (9%), Se (4%), F (26%), Cl (26%), and S (26%).

### Comparative Example 1

### Conventional Photocatalyst/Electrocatalyst g-C₃N₄

5 mmol of carbamide (CH₄N₂O) was calcined at 500° C. for 2 h in a muffle furnace under an air atmosphere to obtain the g-C₃N_{4.}

### Comparative Example 2

A catalyst prepared in Example 5 of Patent 201910475198.1 “A preparation method of a multi-component non-metal-doped carbon nitride photocatalyst” was used as a comparison. A specific preparation method thereof was as follows:
S1, N,N-dimethylformamide (0.01 mol), hydrogen peroxide (0.02 mol), sodium metaphosphate (0.03 mol), and thioacetamide (0.05 mol) were mixed, added with 2 L of deionized water and then stirred at 600 rpm for 7 min to obtain a precursor solution;
S2, dicyandiamide (0.05 mol) was added to the precursor solution, refluxed with heating and stirring for 2 h at 140° C., and then subjected to centrifugal separation to obtain a solid product;
S3, the solid product was separately washed three times with absolute ethanol and deionized water in sequence, vacuum dried at 60° C. for 36 h, and then ground to obtain a powder; and
S4, in the presence of nitrogen, the powder obtained in step S3 was heated to 700° C. at 6° C./min to allow calcination for 4 h, and then ball milled to obtain a quaternary non-metal-doped carbon nitride photocatalyst (TDCN) including nitrogen, oxygen, sulfur, and phosphorus.

### Evaluation of Catalytic Activity

### Test Example 1

### Evaluation of Photocatalytic Reaction Activity

(1) Photocatalytic hydrogen production: 1.5 mg to 5.0 mg of the catalyst was ultrasonically dispersed in a 50 mL Pyrex bottle containing 4 mL of deionized water and an appropriate amount of 10 ppm methylene blue pollutant. The bottle was bubbled with Ar gas for 15 min to remove O₂ and then reacted under the illumination of a 150 mW cm⁻² Xe light source for a specific time. A production level of H₂ was measured by gas chromatography, while a degradation rate of methyl orange was measured by a UV spectrophotometer.
(2) Photocatalytic carbon dioxide reduction: 10 mg of the catalyst was dispersed on one side of an inner wall of the 50 mL Pyrex bottle, and 60 μL of deionized water was added dropwise on a bottom of the bottle. The bottle was air-blown with CO₂ for 15 min to remove O₂ and add CO₂. The bottle was reacted under light source irradiation of Xe lamp (150 mW cm⁻²) for 3 h. A resulting product CO was determined by gas chromatography. A band gap of the catalyst was calculated by measuring the UV-visible diffuse reflectance spectrum.

### Test Example 2

### Evaluation of Electrocatalytic Water Splitting Activity for Hydrogen Production

The electrocatalytic water splitting of catalytic material for hydrogen production was conducted in the three-electrode system. A reference electrode was Hg/HgO, a working electrode was a glassy carbon electrode, a counter electrode was a platinum electrode, and an electrolyte was a 1.0 mol/L KOH solution. The impedance spectra of the catalyst were uniformly tested at an overpotential of 100 mV and then fitted to obtain specific values. A higher impedance (R_{ct}) value indicated less conductivity.

### Test Example 3

### Evaluation of Sodium-Ion Battery Activity

A sample, carbon black, and a sodium alginate binder were mixed at a mass ratio of 70:20:10 to obtain a slurry. In a test system, sodium foil was used as a counter electrode, a mixture of 1 mol/L NaPF₆ and fluoroethylene carbonate/dimethyl carbonate (FEC/DMC, at a volume ratio of 1:1) was used as an electrolyte, and Celgard 3501 as a separator to assemble the sodium-ion battery.

TABLE 1
Evaluation results of photocatalytic hydrogen production
activity coupled with organic pollutant degradation

| | Reaction rate | Complete degradation time |
|---|---|---|
| Material | (μmol g⁻¹ h⁻¹) | of methylene blue (min) |
| Example 1 | 1512.5 | 80 |
| Example 2 | 972.3 | 90 |
| Example 3 | 812.5 | 180 |
| Example 4 | 876.4 | 120 |
| Example 5 | 888.6 | 120 |
| Example 6 | 935.4 | 110 |
| Example 7 | 931.1 | 100 |
| Example 8 | 833.4 | 160 |
| Example 9 | 804.8 | 180 |
| Comparative Example 1 | 202.2 | 360 |
| Comparative Example 2 | 304.5 | 280 |

TABLE 2
Evaluation results of photocatalytic
carbon dioxide reduction activity

| Material | Band gap (eV) | Reaction rate (μmol g⁻¹ h⁻¹) |
|---|---|---|
| Example 1 | 1.8 | 36.5 |
| Example 2 | 2.0 | 28.4 |
| Example 3 | 1.3 | 25.2 |
| Example 4 | 0.3 | 27.5 |
| Example 5 | 1.4 | 24.3 |
| Example 6 | 1.3 | 23.6 |
| Example 7 | 2.2 | 24.1 |
| Example 8 | 1.7 | 28.1 |
| Example 9 | 3.1 | 25.4 |
| Comparative Example 1 | 2.7 | 12.6 |
| Comparative Example 2 | 2.5 | 14.3 |

TABLE 3
Evaluation results of electrocatalytic water
splitting activity for hydrogen production

| | Impedance | Overpotential at 10 mA cm⁻² |
|---|---|---|
| Material | (R_{ct}, Ω) | (mV) |
| Example 1 | 9.4 | 81.2 |
| Example 2 | 10.1 | 84.3 |
| Example 3 | 6.3 | 88.1 |
| Example 4 | 1.1 | 85.6 |
| Example 5 | 8.6 | 90.7 |
| Example 6 | 8.2 | 96.4 |
| Example 7 | 12.3 | 90.6 |
| Example 8 | 9.2 | 84.5 |
| Example 9 | 13.4 | 91.2 |
| Comparative Example 1 | 18.2 | 300.5 |
| Comparative Example 2 | 15.3 | 188.6 |

TABLE 4
Evaluation results of sodium-ion battery activity

| Material | Specific capacity (mAh g⁻¹) |
|---|---|
| Example 1 | 670.3 |
| Example 7 | 602.5 |
| Comparative Example 1 | 161.4 |
| Comparative Example 2 | 93.3 |

To sum up, in the present disclosure: compared with the photoelectrocatalysts of Comparative Examples 1 to 2, the non-metallic high-entropy compounds prepared in Examples 1 to 9 showed a catalytic reaction activity for hydrogen production by high-efficiency photocatalytic/electrocatalytic water splitting, carbon dioxide reduction, or organic pollutant degradation.

Finally, it should be noted that the above embodiments are merely intended to describe the technical solutions of the present disclosure, rather than to limit the present disclosure. Although the present disclosure is described in detail with reference to the above embodiments, persons of ordinary skill in the art should understand that they may still make modifications to the technical solutions described in the above embodiments or make equivalent replacements to some or all technical features thereof, without departing from the essence of the technical solutions in the embodiments of the present disclosure.

What is claimed is:

1. A non-metallic high-entropy compound, comprising at least five non-metallic elements, wherein each of the at least five non-metallic elements has a molar proportion of 0.1% to 99.0%, and a total atomic proportion of the at least five non-metallic elements are 100%.

2. The non-metallic high-entropy compound according to claim 1, wherein the non-metallic elements are selected from the group consisting of hydrogen, boron, carbon, nitrogen, oxygen, fluorine, phosphorus, sulfur, selenium, chlorine, bromine, iodine, and silicon.

3. A preparation method of the non-metallic high-entropy compound according to claim 1, comprising the following steps:
S1, mixing at least five non-metallic element sources evenly to obtain a precursor solution; and
S2, converting the precursor solution into the non-metallic high-entropy compound through solvothermal polymerization, vapor deposition, or electrochemical deposition.

4. The preparation method according to claim 3, wherein the non-metallic elements are selected from the group consisting of hydrogen, boron, carbon, nitrogen, oxygen, fluorine, phosphorus, sulfur, selenium, chlorine, bromine, iodine, and silicon.

5. The preparation method according to claim 3, wherein the non-metallic element source is one or a combination of two or more selected from the group consisting of an inorganic non-metallic acid, an inorganic non-metallic oxide, and a non-metallic organic substance.

6. The preparation method according to claim 4, wherein the non-metallic element source is one or a combination of two or more selected from the group consisting of an inorganic non-metallic acid, an inorganic non-metallic oxide, and a non-metallic organic substance.

7. The preparation method according to claim 3, wherein the non-metallic element source comprises but is not limited to boric acid, hydrogen iodide, diboron trioxide, cyanuric chloride, ethoxy(pentafluoro)cyclotriphosphazene, thioacetamide, methyl-hydroselenide, trimethylsilyl acetate, tri-tert-butyl borate, and carbamide.

8. The preparation method according to claim 4, wherein the non-metallic element source comprises but is not limited to boric acid, hydrogen iodide, diboron trioxide, cyanuric chloride, ethoxy(pentafluoro)cyclotriphosphazene, thioacetamide, methyl-hydroselenide, trimethylsilyl acetate, tri-tert-butyl borate, and carbamide.

9. The preparation method according to claim 3, wherein the mixing comprises but is not limited to mixing by dissolving, mixing by stirring, and mixing by grinding; and
during the mixing by dissolving, the at least five non-metallic element sources are uniformly dispersed under stirring in a mixed solvent of ethanol and water at a volume ratio of 1:(0.5-1.5).

10. The preparation method according to claim 4, wherein the mixing comprises but is not limited to mixing by dissolving, mixing by stirring, and mixing by grinding; and
during the mixing by dissolving, the at least five non-metallic element sources are uniformly dispersed under stirring in a mixed solvent of ethanol and water at a volume ratio of 1:(0.5-1.5).

11. The preparation method according to claim 3, wherein the solvothermal polymerization comprises one of a hydrothermal reaction and a calcination polymerization reaction;
the hydrothermal reaction is conducted at 80° C. to 200° C. for 6 h to 36 h; and
the calcination polymerization reaction is conducted at 500° C. to 700° C. for 1 h to 4 h.

12. The preparation method according to claim 4, wherein the solvothermal polymerization comprises one of a hydrothermal reaction and a calcination polymerization reaction;
the hydrothermal reaction is conducted at 80° C. to 200° C. for 6 h to 36 h; and
the calcination polymerization reaction is conducted at 500° C. to 700° C. for 1 h to 4 h.

13. The preparation method according to claim 3, wherein the vapor deposition specifically comprises: subjecting a vapor of the precursor solution to a reaction in a tubular furnace with an inert gas at a bubbling gas flow rate of 40 mL/min to 60 mL/min and a roasting temperature of 500° C. to 700° C. for 8 h to 12 h.

14. The preparation method according to claim 4, wherein the vapor deposition specifically comprises: subjecting a vapor of the precursor solution to a reaction in a tubular furnace with an inert gas at a bubbling gas flow rate of 40 mL/min to 60 ml/min and a roasting temperature of 500° C. to 700° C. for 8 h to 12 h.

15. The preparation method according to claim 3, wherein the electrochemical deposition specifically comprises: connecting an electrochemical workstation to the precursor solution to construct a three-electrode system, and conducting a reaction at a constant voltage of −20 V for 8 h to 12 h.

16. The preparation method according to claim 4, wherein the electrochemical deposition specifically comprises: connecting an electrochemical workstation to the precursor solution to construct a three-electrode system, and conducting a reaction at a constant voltage of −20 V for 8 h to 12 h.

17. A use method of the non-metallic high-entropy compound according to claim 1, comprising using the non-metallic high-entropy compound in hydrogen production by photocatalytic/electrocatalytic decomposition, carbon dioxide reduction, organic pollutant degradation, or an energy-storage electrode material.

18. The use method according to claim 17, wherein the non-metallic elements are selected from the group consisting of hydrogen, boron, carbon, nitrogen, oxygen, fluorine, phosphorus, sulfur, selenium, chlorine, bromine, iodine, and silicon.
